(19) United States
(12) Patent Application Publication
(10) Pub. No.: US 2017/0077198 A1
(43) Pub. Date: Mar. 16, 2017

(54) COMPOSITE LAYER AND METHOD FOR MANUFACTURING THE SAME, AND OLED DEVICE

(71) Applicant: BOE TECHNOLOGY GROUP CO., LTD., Beijing (CN)

(72) Inventors: Lifang SONG, Beijing (CN); Ze LIU, Beijing (CN)

(73) Assignee: BOE TECHNOLOGY GROUP CO., LTD., Beijing (CN)

(21) Appl. No.: 15/137,871

(22) Filed: Apr. 25, 2016

(30) Foreign Application Priority Data
Sep. 10, 2015 (CN) 201510574101.4

(51) Int. Cl. H01L 27/32; H01L 51/56; H01L 51/00; H01L 51/52

(52) U.S. Cl. CPC H01L 27/3258; H01L 51/5206; H01L 51/56; H01L 51/004; H01L 2251/5369; H01L 2251/303

(57) ABSTRACT

The present disclosure discloses a composite layer and a method for manufacturing the same, and an OLED device comprising the composite layer. The composite layer comprises a planarization layer and an anode layer that is connected with the planarization layer, wherein the planarization layer is made of a composite material comprising polymethylmethacrylate and a nanoparticle, and the nanoparticle is a silicon dioxide, titanium dioxide, aluminium oxide or zinc oxide nanoparticle. The method for manufacturing the composite layer comprises: obtaining a composite material comprising polymethylmethacrylate and a nanoparticle by reacting a sol of the nanoparticle or a nanoparticle surface-modified by a silane coupling agent with methylmethacrylate; obtaining a planarization layer by spin coating, exposing and developing the composite material; and obtaining a composite layer by forming an anode layer on the planarization layer.

### CROSS-REFERENCE TO RELATED APPLICATION

This application claims priority to Chinese Patent Application No. 201510574101.4 filed on Sep. 10, 2015, the disclosure of which is incorporated in its entirety by reference herein.

### TECHNICAL FIELD

The present disclosure relates to the field of electronic devices, in particular to a composite layer and a method for manufacturing the same, and an Organic Light-Emitting Diode (OLED) device.

### BACKGROUND

According to different light emitting directions from the device, organic electroluminescent device may be divided into two types of structures: bottom emission device (BEOLED) and top emission device (OLED). The light emitted by a top emission device emerges from the top of the device, thus it will not be influenced by the bottom driver panel of the device, so that the aperture ratio may be improved effectively, which is favorable for the integration of the device and the bottom drive circuit. Meanwhile, the top emission device also has the advantages of improving the device efficiency, narrowing the spectrum and improving the color purity, etc. Therefore, top emission devices have very good development prospect.

The structure of a top emission device is as shown in FIG. 1, which in sequence includes glass 1, a gate 2, a GI 3, an active layer 4, an S/D 5, a passivation layer (PVX) 6, a planarization layer 7, an anode 8, a luminescent layer 9 and a cathode 10. At present, a material generally used for the planarization layer is polymethylmethacrylate (PMMA), which has excellent light transmittance and electric insulativity but poor heat resistance, wear resistance and toughness. When polymethylmethacrylate is employed for a planarization layer, there are the following 3 disadvantages: first of all, the planarization layer is relatively transparent, thus a TFT tends to be influenced by ultraviolet light, which causes the deterioration of the display performance of the device; next, the anode is sputtered on the planarization layer, wherein the anode is made from an inorganic material ITO and the planarization layer is made of an organic material, which have different interfaces, thus the anode has a weak adhesive force with the planarization layer, and it tends to peel off; further, the heat resistance of the planarization layer is not high enough, as a result, the selection of the material for each luminescent layer will be limited.

### SUMMARY

The technical problem to be solved by the present disclosure is to provide a composite layer and a method for manufacturing the same, and an OLED device, wherein the planarization layer has good adhesivity with the anode, and it does not tend to peel off.

According to one embodiment of the present disclosure, a composite layer is provided, which includes a planarization layer and an anode layer that is connected with the planarization layer, wherein the planarization layer is made of a composite material comprising polymethylmethacrylate and a nanoparticle;

the nanoparticle is a silicon dioxide, titanium dioxide, aluminium oxide or zinc oxide nanoparticle.

In one example, the nanoparticle in the planarization layer is mixed in polymethylmethacrylate or grafted onto the surface of polymethylmethacrylate.

In one example, the mass percentage of the nanoparticle in the composite material is 0.5˜60%.

According to one embodiment of the present disclosure, a method for manufacturing a composite layer is provided, which includes the steps of:

A) obtaining a sol of a nanoparticle by reacting a chloride or metal alkoxide of an element selected from silicon, titanium, aluminium and zinc with absolute ethanol and an ethanol solution of potassium hydroxide;

wherein the nanoparticle is a silicon dioxide, titanium dioxide, aluminium oxide or zinc oxide nanoparticle;

B) obtaining a composite material comprising polymethylmethacrylate and the nanoparticle by reacting the sol of the nanoparticle with methylmethacrylate in the presence of an initiator;

C) obtaining a planarization layer by spin coating, exposing and developing the composite material; and

D) obtaining a composite layer by forming an anode layer on the planarization layer.

In one example, the viscosity of the composite material comprising polymethylmethacrylate and the nanoparticle in the step B) is 0.5˜5 cp.

In one example, the mass percentage of the nanoparticle in the composite material in the step B) is 0.5˜60%.

In one example, the reaction temperature in the step A) is 60˜80° C., and the reaction time in the step A) is 1˜4 h.

In one example, the reaction temperature in the step B) is 60˜90° C., and the reaction time in the step B) is 1˜4 h.

According to one embodiment of the present disclosure, a method for manufacturing a composite layer is provided, which includes the steps of:

A) adding a nanoparticle into ethanol and dispersing the nanoparticle via ultrasound, then adding a silane coupling agent, performing ultrasonic treatment for homogenization and then removing ethanol, thus obtaining a surface-modified nanomaterial;

wherein the nanoparticle is a silicon dioxide, titanium dioxide, aluminium oxide or zinc oxide nanoparticle;

B) obtaining a composite material comprising polymethylmethacrylate and the nanoparticle by reacting the surface-modified nanomaterial with methylmethacrylate in the presence of a peroxide-type initiator;

C) obtaining a planarization layer by spin coating, exposing and developing the composite material; and

D) obtaining a composite layer by forming an anode layer on the planarization layer.

In one example, the viscosity of the composite material comprising polymethylmethacrylate and the nanoparticle in the step B) is 0.5˜5 cp.

In one example, the mass percentage of the nanoparticle in the composite material in the step B) is 0.5˜60%.

In one example, the reaction temperature in the step B) is 60˜90° C., and the reaction time in the step B) is 1˜4 h.

The present disclosure further discloses an OLED device, which includes the composite layer according to the above technical solution or a composite layer manufactured by the method according to the above technical solution.

In comparison with the prior art, the composite layer of the present disclosure includes a planarization layer and an anode layer that is connected with the planarization layer, wherein the planarization layer is made of a composite material comprising polymethylmethacrylate and a nanoparticle, and the nanoparticle is a silicon dioxide, titanium dioxide, aluminium oxide or zinc oxide nanoparticle. The material used for the planarization layer is a composite material obtained by doping a nanoparticle into polymethylmethacrylate, the nanoparticle such as titanium dioxide, aluminium oxide or the like has an interface property similar to that of the anode layer ITO, thus the two parts in the composite layer have good adhesivity, and the binding force is strong. Moreover, the nanoparticle itself has a function of absorbing or reflecting ultraviolet light, thus when it is doped in polymethylmethacrylate, the ultraviolet light may be screened. Additionally, the thermal decomposition temperature of the composite material comprising polymethylmethacrylate and the nanoparticle is high, thus the heat resistance of the planarization layer in the composite layer made of the composite material is high.

### BRIEF DESCRIPTION OF THE DRAWINGS

FIG. 1 is a structural representation of a top emission device;

FIG. 2 is a structural representation of a composite layer prepared according to the present disclosure;

FIG. 3 is a structural representation of another composite layer prepared according to the present disclosure;

FIG. 4 shows a thermogravimetric curve of the planarization layer of Embodiment 3; and

FIG. 5 shows an ultraviolet spectrum of the planarization layer of Embodiment 4.

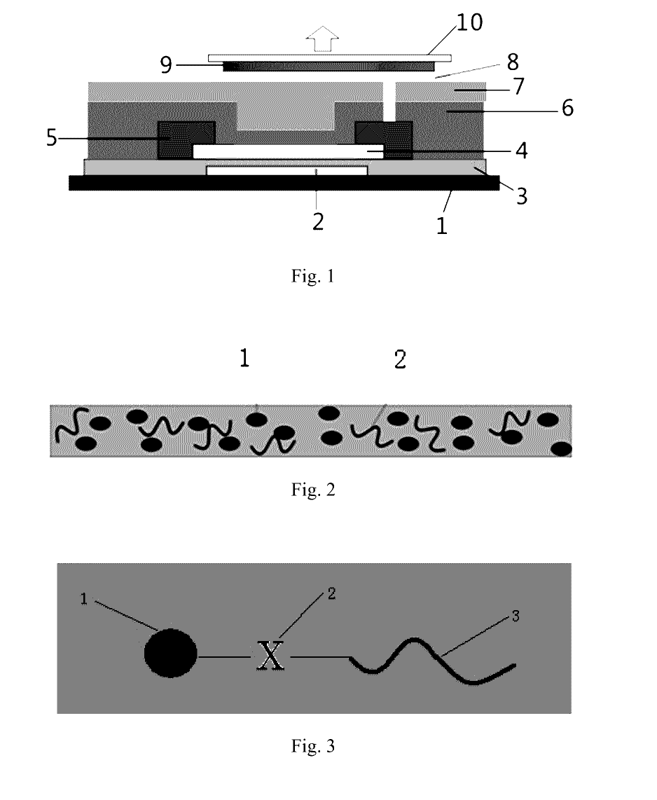

### DETAILED DESCRIPTION

For further understanding the present disclosure, preferred implementation solutions of the present disclosure will be described below in conjunction with the embodiments. However, it should be understood that, these descriptions are only used for further illustrating the characteristics and advantages of the present disclosure, rather than limiting the claims of the present disclosure.

One embodiment of the present disclosure discloses a composite layer, which includes a planarization layer and an anode layer that is connected with the planarization layer, wherein the planarization layer is made of a composite material comprising polymethylmethacrylate and a nanoparticle;

the nanoparticle is a silicon dioxide, titanium dioxide, aluminium oxide or zinc oxide nanoparticle.

In the present disclosure, the composite layer is a part of a top emission device, and includes a planarization layer and an anode layer.

The planarization layer is made of a composite material comprising polymethylmethacrylate and a nanoparticle. The composite material is doped with particles of nano-grain size, and preferably, the grain size is 1˜100 nm. The scale of the nanoparticle is close to wavelength of light, it has the special effects with a large surface area, which is totally different from the properties exhibited by a particle with nonnano-scale grain size. The nanoparticle is mixed in polymethylmethacrylate or grafted onto the surface of polymethylmethacrylate, so that the interface of polymethylmethacrylate is converted into an interface on which organic and inorganic particles exist mixedly. Preferably, the mass percentage of the nanoparticle in the composite material is 0.5˜60%. The nanoparticle is a silicon dioxide, titanium dioxide, aluminium oxide or zinc oxide nanoparticle. These nanoparticles have properties similar to those of ITO that functions as the anode layer, and when these nanoparticles are mixed in polymethylmethacrylate or grafted onto the surface of polymethylmethacrylate, the binding force between the planarization layer and the anode layer can be enhanced. Moreover, the nanoparticle itself has the function of absorbing or reflecting ultraviolet light, and when it is doped in polymethylmethacrylate, the ultraviolet light may be screened. Additionally, the thermal decomposition temperature of the composite material comprising polymethylmethacrylate and the nanoparticle is high, thus the heat resistance of the planarization layer in the composite layer made of the composite material is high.

The anode layer is made of an ITO material, it has properties similar to those of the nanoparticle, and it has good adhesivity with the planarization layer. ITO is sputtered on the planarization layer to form an anodized layer, which does not tends to peel off.

According to one embodiment of the present disclosure, a method for manufacturing a composite layer is provided, which includes the steps of:

A) obtaining a sol of a nanoparticle by reacting a chloride or metal alkoxide of an element selected from silicon, titanium, aluminium and zinc with absolute ethanol and an ethanol solution of potassium hydroxide;

wherein the nanoparticle is a silicon dioxide, titanium dioxide, aluminium oxide or zinc oxide nanoparticle;

B) obtaining a composite material comprising polymethylmethacrylate and the nanoparticle by reacting the sol of the nanoparticle with methylmethacrylate in the presence of an initiator;

C) obtaining a planarization layer by spin coating, exposing and developing the composite material; and

D) obtaining a composite layer by forming an anode layer on the planarization layer.

According to the present disclosure, first of all, a sol of a nanoparticle is obtained by reacting a chloride or metal alkoxide of an element selected from silicon, titanium, aluminium and zinc with absolute ethanol and an ethanol solution of potassium hydroxide, preferably as follows:

A chloride or metal alkoxide of any one of silicon, titanium, aluminium and zinc is selected and added into absolute ethanol and stirred for 1˜3 hours, then an ethanol solution of potassium hydroxide is added dropwise, and the above solution is heated and refluxed for 1˜4 hours in a water bath of 60˜80° C., thus a sol of a nanoparticle is obtained.

The chloride or the metal alkoxide of any one of silicon, titanium, aluminium and zinc may be zinc chloride, butyl titanate or tetrahexyl orthosilicate, etc. The mass of the absolute ethanol added is equal to the mass of the chloride or metal alkoxide of any one of silicon, titanium, aluminium and zinc added. The concentration of the ethanol solution of potassium hydroxide is 0.1M. The nanoparticle obtained is a silicon dioxide, titanium dioxide, aluminium oxide or zinc oxide nanoparticle.

After the sol of the nanoparticle is obtained, a composite material comprising polymethylmethacrylate and the nanoparticle is obtained by reacting the sol of the nanoparticle with methylmethacrylate in the presence of an initiator. Preferably, the initiator is azodiisobutyronitrile. Preferably, the mass percentage of the nanoparticle in the composite material is 0.5˜60%. The reaction temperature is 60˜90° C., and the reaction time is 1˜4 h. Preferably, the viscosity of the composite material comprising polymethylmethacrylate and the nanoparticle finally obtained is 0.5˜5 cp. A composite material comprising polymethylmethacrylate and the nanoparticle with a viscosity of 0.5˜5 cp is selected, which is favorable for the subsequent processes of spin coating, etc., so that a flat planarization layer may be formed. If its flatness is decreased, the surface of the anode ITO will be uneven, and the luminescence will be influenced.

After the composite material comprising polymethylmethacrylate and the nanoparticle is obtained, a planarization layer is obtained by spin coating, exposing and developing the composite material. The matrix for spin coating is a passivation layer. In the present disclosure, the method for manufacturing the planarization layer is not particularly limited, and it may be manufactured according to an existing method.

After the planarization layer is obtained, ITO is sputtered on the planarization layer to obtain an anode layer, thus a composite layer is obtained. In the present disclosure, the method for manufacturing the anode layer is not particularly limited either, and it may be manufactured according to an existing method.

In the case of the composite layer manufactured by such a method, in terms of the planarization layer concerned, its nanoparticles are mixed in polymethylmethacrylate. FIG. 2 is a structural representation of a composite layer prepared according to the present disclosure. In FIG. 2, 1 is a nanoparticle, and 2 is polymethylmethacrylate. In the planarization layer obtained by the method, nanoparticles are mixed in polymethylmethacrylate, thus the planarization layer includes the mixing interface of organic and inorganic nanoparticles, the inorganic nanoparticles show good affinity with the ITO in the anode layer, and the binding force between the planarization layer and the anode layer can be enhanced.

According to one embodiment of the present disclosure, a method for manufacturing a composite layer is further provided, which includes the steps of:

A) adding a nanoparticle into ethanol and dispersing the nanoparticle via ultrasound, then adding a silane coupling agent, performing ultrasonic treatment for homogenization and then removing ethanol, thus obtaining a surface-modified nanomaterial;

wherein the nanoparticle is a silicon dioxide, titanium dioxide, aluminium oxide or zinc oxide nanoparticle;

B) obtaining a composite material comprising polymethylmethacrylate and the nanoparticle by reacting the surface-modified nanomaterial with methylmethacrylate in the presence of a peroxide-type initiator;

C) obtaining a planarization layer by spin coating, exposing and developing the composite material; and

D) obtaining a composite layer by forming an anode layer on the planarization layer.

According to the present disclosure, first of all, a nanoparticle is added into ethanol and dispersed via ultrasound, then a silane coupling agent is added, ultrasonic treatment is performed for homogenization and then ethanol is removed, thus a surface-modified nanomaterial is obtained. The nanoparticle is a silicon dioxide, titanium dioxide, aluminium oxide or zinc oxide nanoparticle. Preferably, the silane coupling agent is KH-570. The amount of the silane coupling agent added is 5˜10% by mass of ethanol. Preferably, the mass fraction of ethanol is 15%˜25%, and more preferably, 20%. Preferably, the mass of ethanol added is equal to the mass of the nanoparticles.

After the surface-modified nanomaterial is obtained, it is reacted with methylmethacrylate in the presence of a peroxide-type initiator, and a composite material comprising polymethylmethacrylate and the nanoparticle is obtained. Preferably, the peroxide-type initiator is tert-butyl hydroperoxide (TBHP) or benzoyl peroxide (BPO). Preferably, the mass percentage of the nanoparticle in the composite material is 0.5˜60%. Preferably, the viscosity of the composite material comprising polymethylmethacrylate and the nanoparticle is 0.5˜5 cp. A composite material comprising polymethylmethacrylate and the nanoparticle with a viscosity of 0.5˜5 cp is employed, which is favorable for the subsequent processes of spin coating, etc., so that a flat planarization layer may be formed. If its flatness is decreased, the surface of the anode ITO will be uneven, and the luminescence will be influenced. Preferably, the reaction temperature is 60˜90° C., and preferably, the reaction time is 1˜4 h.

After the composite material comprising polymethylmethacrylate and the nanoparticle is obtained, a planarization layer is obtained by spin coating, exposing and developing the composite material. The matrix for spin coating is a passivation layer. In the present disclosure, the method for manufacturing the planarization layer is not particularly limited, and it may be manufactured according to an existing method.

After the planarization layer is obtained, ITO is sputtered on the planarization layer to obtain an anode layer, thus a composite layer is obtained. In the present disclosure, the method for manufacturing the anode layer is not particularly limited either, and it may be manufactured according to an existing method.

In case of the composite layer manufactured by the method, in terms of the planarization layer concerned, its nanoparticles are grafted onto the surface of polymethylmethacrylate. FIG. 3 is a structural representation of another composite layer prepared according to the present disclosure. In FIG. 3, 1 is a nanoparticle, 2 is a linking group, and 3 is PMMA. In the planarization layer obtained by the method, nanoparticles are grafted onto the surface of polymethylmethacrylate, thus the planarization layer includes a mixing interface of organic and inorganic nanoparticles, the inorganic nanoparticles show good affinity with the ITO in the anode layer, and the binding force between the planarization layer and the anode layer can be enhanced.

According to one embodiment of the present disclosure, an OLED device is further provided, which includes the composite layer according to the above technical solution or a composite layer manufactured by the method according to the above technical solution. The manufacturing method is as follows: sequentially, a composite material comprising polymethylmethacrylate and the nanoparticle is spin-coated on a passivation layer, and a planarization layer is formed by exposing and developing, then an anode layer is formed on the planarization layer, and finally other layers in the OLED device are manufactured.

For further understanding the present disclosure, a composite layer and a method for manufacturing the same and an OLED device according to the present disclosure will be illustrated in detail below in conjunction with the embodiments, but the protection scope of the present disclosure will not be limited to the embodiments below.

### Embodiment 1

1) Butyl titanate is selected as a precursor, it is added into an equal amount of absolute ethanol and stirred vigorously for 1 h, then a KOH/ethanol solution is added dropwise, and the above solution is heated and refluxed for 2 h in a water bath of 60° C., thus a sol of a nanoparticle is prepared;

2) Methylmethacrylate (MMA) and an initiator azodiisobutyronitrile (AIBN) are added into the sol prepared, with the content of the nanoparticles being controlled at 1%, and it is stirred vigorously for 2 h at 60° C., with the viscosity of the polymer-nanoparticle composite material being controlled at 5 cp, and a planar and homogeneous planarization layer is made of the composite material via spin-coating, and then it is exposed and developed via an existing process;

3) ITO is sputtered on the planarization layer to form an anode layer, thus a composite layer is obtained.

When it continues to manufacture a luminescent layer and a cathode on the composite layer, no phenomenon of anode peeling-off occurs in 95% of the cases.

### Embodiment 2

1) Tetrahexyl orthosilicate is selected as a precursor, it is added into an equal amount of absolute ethanol and stirred vigorously for 1 h, then a KOH/ethanol solution is added dropwise, and the above solution is heated and refluxed for 2.5 h in a water bath of 60° C., thus a sol of a nanoparticle is prepared;

2) Methylmethacrylate (MMA) and an initiator azodiisobutyronitrile (AIBN) are added into the sol prepared, with the content of the nanoparticles being controlled at 30%, and it is stirred vigorously for 3 h at 70° C., with the viscosity of the polymer-nanoparticle composite material being controlled at 3 cp, and a planar and homogeneous planarization layer is made of the composite material via spin-coating, and then it is exposed and developed via an existing process;

3) ITO is sputtered on the planarization layer to form an anode layer, thus a composite layer is obtained.

When it continues to manufacture a luminescent layer and a cathode on the composite layer, no phenomenon of anode peeling-off occurs in 95% of the cases.

### Embodiment 3

1) Aluminium oxide is added into an equal mass of ethanol and dispersed via ultrasound, then silane coupling agent KH-570 is added, ultrasonic treatment is performed for homogenizing the solution and then the solvent is removed by suction filtration, thus a surface-modified nanomaterial is obtained;

wherein the mass fraction of ethanol is 20%;

2) An peroxide-type initiator benzoyl peroxide (BPO) and methylmethacrylate (MMA) are added in sequence into the modified nanomaterial, with the content of the nanoparticles being controlled at 40%, and it is stirred vigorously for 2 h at 80° C., thus a polymer-nanoparticle composite material is obtained by suction-filtering the solution; the composite material is dissolved in a corresponding solvent, the viscosity of the composite material comprising polymethylmethacrylate and the nanoparticle is 1.5 cp, and a planar and homogeneous planarization layer is manufactured via spin-coating, then it is exposed and developed via an existing process;

3) ITO is sputtered on the planarization layer to form an anode layer, thus a composite layer is obtained.

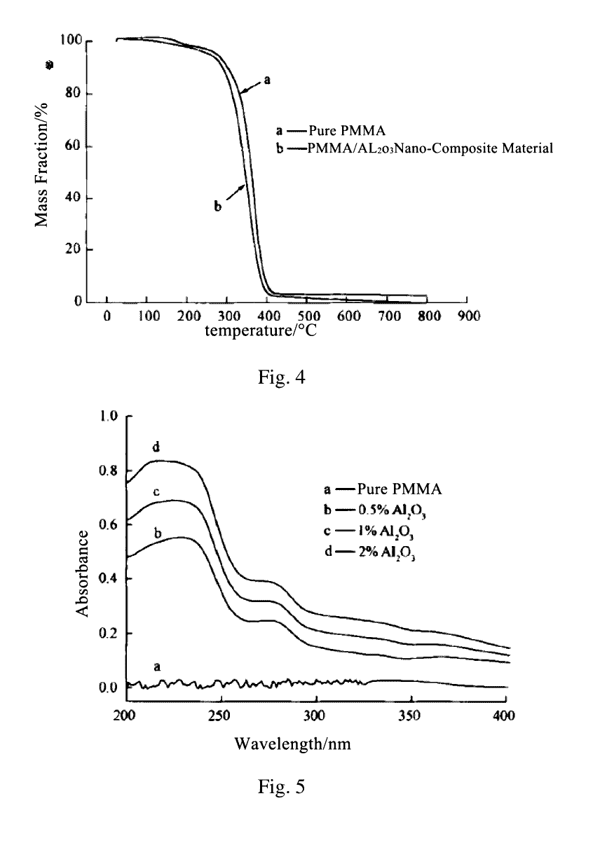

The thermogravimetric curve of the planarization layer in the composite layer prepared are tested. In FIG. 4, curve a shows a thermogravimetric curve of pure PMMA, and curve b shows a thermogravimetric curve of a planarization layer of Embodiment 3.

It may be known from FIG. 4 that, the planarization layer in the composite layer of the present disclosure has a high heat resistance.

When it continues to manufacture a luminescent layer and a cathode on the composite layer, no phenomenon of anode peeling-off occurs in 95% of the cases.

### Embodiment 4

1) Aluminium oxide is added into an equal mass of ethanol and dispersed via ultrasound, then silane coupling agent KH-570 is added, ultrasonic treatment is performed for homogenizing the solution and then the solvent is removed by suction filtration, thus a surface-modified nanomaterial is obtained;

wherein the mass fraction of ethanol is 20%;

2) An peroxide-type initiator benzoyl peroxide (BPO) and methylmethacrylate (MMA) are added in sequence into the modified nanomaterial, with the content of the nanoparticles being controlled at 0.5%, 1% and 2%, and it is stirred vigorously for 2 h at 80° C., thus a polymer-nanoparticle composite material is obtained by suction-filtering the solution; the composite material is dissolved in a corresponding solvent, the viscosity of the composite material comprising polymethylmethacrylate and the nanoparticle is 1.5 cp, and a planar and homogeneous planarization layer is manufactured via spin-coating, then it is exposed and developed via an existing process;

3) ITO is sputtered on the planarization layer to form an anode layer, thus a composite layer is obtained.

The ultraviolet spectrum of the planarization layer in the composite layer prepared are tested. In FIG. 5, curve a shows an ultraviolet spectrum of pure PMMA, and curves b˜d show ultraviolet spectrums of the planarization layer of Embodiment 4.

It may be known from FIG. 5 that, the planarization layer in the composite layer of the present disclosure has an effect of screening ultraviolet light.

When it continues to manufacture a luminescent layer and a cathode on the composite layer, no phenomenon of anode peeling-off occurs in 95% of the cases.

### Embodiment 5

1) Zinc oxide is added into an equal mass of ethanol and dispersed via ultrasound, then silane coupling agent KH-570 is added, ultrasonic treatment is performed for homogenizing the solution and then the solvent is removed by suction filtration, thus a surface-modified nanomaterial is obtained;

wherein the mass fraction of ethanol is 20%.

2) An peroxide-type initiator benzoyl peroxide (BPO) and methylmethacrylate (MMA) are added in sequence into the modified nanomaterial, with the content of the nanoparticles being controlled at 1%, and it is stirred vigorously for 3.5 h at 60° C., thus a polymer-nanoparticle composite material is obtained by suction-filtering the solution; the composite material is dissolved in a corresponding solvent, the viscosity of the composite material comprising polymethylmethacrylate and the nanoparticle is 5 cp, and a planar and homogeneous planarization layer is manufactured via spin-coating, then it is exposed and developed via an existing process;

3) ITO is sputtered on the planarization layer to form an anode layer, thus a composite layer is obtained.

When it continues to manufacture a luminescent layer and a cathode on the composite layer, no phenomenon of anode peeling-off occurs in 95% of the cases.

### Embodiment 6

Glass 1, a Gate 2, a GI 3, an active layer 4, an S/D 5 and a passivation layer (PVX) 6 are manufactured in sequence according to the existing methods. Then, according to the method of Embodiment 1, a planarization layer is prepared on the passivation layer via spin-coating, exposing and developing, an anode layer is formed via sputtering, and a luminescent layer and a cathode are manufactured in sequence on the left and the right, thus a top emission (OLED) device is obtained.

### Comparative Embodiment 1

Polymethacrylate is selected to form a planarization layer, and then ITO is sputtered on the planarization layer to obtain an anode layer.

When it continues to manufacture a luminescent layer and a cathode on the anode layer, a phenomenon of anode peeling-off occurs in more than 10% of the cases.

The above embodiments are only illustrated for aiding the understanding of the method of the present disclosure and its core concept. It should be pointed out that, for one of ordinary skills in the art, various improvements and modifications may be made to the present disclosure without departing from the principles of the present disclosure, and these improvements and modifications also fall into the protection scope of the claims of the present disclosure.

With the above illustration of the embodiments disclosed, those skilled in the art can implement or utilize the present disclosure. Various modifications to these embodiments are apparent to those skilled in the art, and the general principle defined herein may be realized in other embodiments without departing from the spirit or scope of the present disclosure. Therefore, the present disclosure will not be limited to the embodiments illustrated; instead, the present disclosure conforms to the widest range consistent with the principles and novel features disclosed herein.

What is claimed is:

1. A composite layer, comprising: a planarization layer and an anode layer that is connected with the planarization layer,
wherein the planarization layer is made of a composite material comprising polymethylmethacrylate and a nanoparticle; and
the nanoparticle is a silicon dioxide, titanium dioxide, aluminium oxide or zinc oxide nanoparticle.

2. The composite layer according to claim 1, wherein the nanoparticle in the planarization layer is mixed in polymethylmethacrylate or grafted onto a surface of polymethylmethacrylate.

3. The composite layer according to claim 1, wherein a mass percentage of the nanoparticle in the composite material is 0.5˜60%.

4. A method for manufacturing a composite layer, comprising steps of:
A) obtaining a sol of a nanoparticle by reacting a chloride or metal alkoxide of an element selected from silicon, titanium, aluminium and zinc with absolute ethanol and an ethanol solution of potassium hydroxide, wherein the nanoparticle is a silicon dioxide, titanium dioxide, aluminium oxide or zinc oxide nanoparticle;
B) obtaining a composite material comprising polymethylmethacrylate and the nanoparticle by reacting the sol of the nanoparticle with methylmethacrylate in the presence of an initiator;
C) obtaining a planarization layer by spin coating, exposing and developing the composite material; and
D) obtaining a composite layer by forming an anode layer on the planarization layer.

5. The manufacturing method according to claim 4, wherein a viscosity of the composite material comprising polymethylmethacrylate and the nanoparticle in the step B) is 0.5˜5 cp.

6. The manufacturing method according to claim 4, wherein a mass percentage of the nanoparticle in the composite material in the step B) is 0.5˜60%.

7. The manufacturing method according to claim 4, wherein a reaction temperature in the step A) is 60˜80° C. and a reaction time in the step A) is 1˜4 h.

8. The manufacturing method according to claim 4, wherein a reaction temperature in the step B) is 60˜90° C. and a reaction time in the step B) is 1˜4 h.

9. The manufacturing method according to claim 4, wherein the chloride or metal alkoxide of an element selected from silicon, titanium, aluminium and zinc in the step A) is zinc chloride, or butyl titanate, or tetrahexyl orthosilicate.

10. The manufacturing method according to claim 4, wherein the initiator in the step B) is azodiisobutyronitrile.

11. A method for manufacturing a composite layer, comprising steps of:
A) adding a nanoparticle into ethanol and dispersing the nanoparticle via ultrasound, then adding a silane coupling agent, performing ultrasonic treatment for homogenization and then removing ethanol, thus obtaining a surface-modified nanomaterial, wherein the nanoparticle is a silicon dioxide, titanium dioxide, aluminium oxide or zinc oxide nanoparticle;
B) obtaining a composite material comprising polymethylmethacrylate and the nanoparticle by reacting the surface-modified nanomaterial with methylmethacrylate in the presence of a peroxide-type initiator;
C) obtaining a planarization layer by spin coating, exposing and developing the composite material; and
D) obtaining a composite layer by forming an anode layer on the planarization layer.

12. The manufacturing method according to claim 11, wherein the silane coupling agent in the step A) is KH-570.

13. The manufacturing method according to claim 11, wherein an amount of the silane coupling agent added in the step A) is 5˜10% by mass of ethanol.

14. The manufacturing method according to claim 11, wherein a viscosity of the composite material comprising polymethylmethacrylate and the nanoparticle in the step B) is 0.5˜5 cp.

15. The manufacturing method according to claim 11, wherein a mass percentage of the nanoparticle in the composite material in the step B) is 0.5˜60%.

16. The manufacturing method according to claim 11, wherein a reaction temperature in the step B) is 60˜90° C. and a reaction time in the step B) is 1˜4 h.

17. The manufacturing method according to claim 11, wherein the peroxide-type initiator in the step B) is tert-butyl hydroperoxide or benzoyl peroxide.

18. An Organic Light-Emitting Diode (OLED) device, comprising the composite layer according to claim 1.

19. An Organic Light-Emitting Diode (OLED) device, comprising the composite layer manufactured by the method of claim 4.

20. An Organic Light-Emitting Diode (OLED) device, comprising the composite layer manufactured by the method of claim 11.
